(19) United States
(12) Patent Application Publication
(10) Pub. No.: US 2012/0160095 A1
(43) Pub. Date: Jun. 28, 2012

(54) Novel Nanoporous Supported Lyotropic Liquid Crystal Polymer Membranes and Methods of Preparing and Using Same

(75) Inventors: Douglas L. Gin, Longmont, CO (US); Alan W. Weimer, Niwot, CO (US); Xinhua Liang, Rolla, MO (US)

(73) Assignee: The Regents of the University of Colorado, a body corporate

(21) Appl. No.: 13/303,750

(22) Filed: Nov. 23, 2011

Related U.S. Application Data
(60) Provisional application No. 61/417,787, filed on Nov. 29, 2010.

(51) Int. Cl. B01D 71/06; B01D 71/02; C23C 16/44; B01D 53/22; B01D 67/00; B01D 61/14; B01D 69/02

(52) U.S. Cl. 95/45; 210/500.27; 210/500.25; 210/650; 427/245

(57) ABSTRACT

The invention includes a nanoporous LLC polymer membrane wherein ultra-thin films or clusters of inorganic material are deposited inside the porous structure of the LLC polymer membrane. The membranes of the invention have high levels of pore size uniformity, allowing for size discrimination separation, and may be used for separation processes such as gas-phase and liquid-phase separations.

### CROSS-REFERENCE TO RELATED APPLICATION

The present application is entitled to priority under 35 U.S.C. §119(e) to U.S. Provisional Application No. 61/417,787, filed Nov. 29, 2010, which application is incorporated by reference herein in its entirety.

### STATEMENT REGARDING FEDERALLY SPONSORED RESEARCH OR DEVELOPMENT

This invention was made with government support under grant number CMI0400292 awarded by the National Science Foundation. The government has certain rights in the invention.

### BACKGROUND OF THE INVENTION

With increasing energy costs, gas separation membranes are likely to play an increasingly important role in reducing the environmental impact and the costs of industrial processes (R. W. Baker, “Future directions of membrane gas separation technology”, Industrial & Engineering Chemistry Research 2002, 41(6):1393-1411; W. J. Koros, “Evolving beyond the thermal age of separation processes: Membranes can lead the way”, AIChE Journal 2004, 50(10):2326-2334; R. D. Noble, R. Agrawal, “Separations research needs for the 21^{st} century”, Industrial & Engineering Chemistry Research 2005, 44(9):2887-2892).

Commercially important gas separations include H₂ purification from light gases related to coal gasification, and CO₂ removal from CH₄ in natural gas processing, with gas molecule size differences ranging from 0.02 nm (O₂/N₂) to 0.09 nm (H₂/CH₄). Dense membranes can separate gas mixtures based on competitive adsorption and/or differences in diffusion rates, whereas porous membranes can separate gas mixtures via molecular discrimination or sieving (J. G. Wijmans, R. W. Baker, “The solution-diffusion model-A review”, Journal of Membrane Science 1995, 107(1-2):1-21; D. L. Gin, J. E. Bara, R. D. Noble, B. J. Elliott, “Polymerized lyotropic liquid crystal assemblies for membrane applications”, Macromolecular Rapid Communications 2008, 29(5):367-389).

Ideally, a membrane should exhibit both high flux and high selectivity. Membrane selective layers with appropriate material properties and sufficiently low amounts of defects allow high selectivity, while thin selective layers allow high flux. Nanoporous membranes with small pores (e.g., less than 0.5 nm) are most useful in effectively separating gas mixtures by molecular sieving. However, smaller pore sizes are more difficult to control and make reproducibly; and normally a tradeoff exists between flux and selectivity (D. Freeman, “Basis of permeability/selectivity tradeoff relations in polymeric gas separation membranes”, Macromolecules 1999, 32(2):375-380).

Another important application for nanoporous membranes is liquid water purification and desalination. There is an increasing interest in developing cost-effective ways of providing fresh water for human use in regions where the availability of fresh water is limited. Reverse osmosis (RO) is a membrane process that removes hydrated salt ions (<1 nm in diameter) and larger solutes from water, irrespective of their charge, using dense polymer materials (S. S. Sablani, M. F. A. Goosen, R. AI-Belushi, M. Wilf; “Concentration polarization in ultrafiltration and reverse osmosis: a critical review”, Desalination 2001, 141 (3):269-289). This is the reverse of the normal osmosis process, which is the natural movement of solvent from an area of low solute concentration to an area of high solute concentration when no external pressure is applied. Since the water molecules have a kinetic diameter of 0.25 nm, and hydrated metal salt ions (e.g., Na⁺ (aq): 0.72 nm diameter) (E. R. Nightingale, “Phenomenological theory of ion solution—effective radii of hydrogen ions”, Journal of Physical Chemistry 1959, 63(9):1381-1387) typically have diameters of >0.7 nm, it is believed that in dense RO membranes, hydrated salt ions are “size-excluded” through the intrinsic ≦0.5 nm interstitial voids between the polymer chains.

Porous nanofiltration (NF) membranes (i.e., containing discrete nanometer-size pores) are also used for water purification (A. Bhattacharya, P. Ghosh, “Nanofiltration and reverse osmosis membranes: Theory and application in separation of electrolytes”, Reviews in Chemical Engineering 2004, 20(1-2):111-173). NF membranes reject molecular solutes 1-10 nm in diameter via size- and charge-based exclusion but are limited in water desalination applications because they can only partially reject small monovalent ions. Unfortunately, current RO and NF membrane production methods (e.g., interfacial polymerization) provide very little control over the size and distribution of the interstitial voids or nanopores.

The design, manufacture, and control of polymers with effective pore sizes on the <0.5 nm scale useful for molecular-size-based light gas separations and controllable water purification/desalination applications are extremely difficult. Only inorganic nanoporous crystalline materials, such as zeolites (J. Caro, M. Noack, P, Kolsch, R. Schafer, “Zeolite membranes—state of their development and perspective”, Microporous and Mesoporous Materials 2000, 38(1):3-24), and sensitive biological constructs, such as protein-based cell membrane ion channels (D. H. Kim, “Novel cation—selective mechanosensitive ion channel in the atrial cell membrane”, Circulation Research 1993, 72(1):225-231), are known to exhibit well-defined nanopores in this size range. However, these latter two materials are not ideal or amenable to polymer membrane construction or use because of, respectively, their brittle mechanical properties and environmental sensitivity. Martin and co-workers have shown that polymeric membranes with inside diameters of molecular dimensions (<1 nm) can be prepared using an electroless plating procedure to deposit a gold nanotubule within each pore, and this kind of polymeric membranes can be used for the separation of small molecules on the basis of molecular size (K. B. Jirage, J. C. Hulteen, C. R, Martin, “Nanotubule-based molecular-filtration membranes”, Science 1997, 278(5338):655-658; C. R. Martin, M, Nishizawa, K. Jirage, M. S. Kang, S. B. Lee, “Controlling ion-transport selectivity in gold nanotubule membranes”, Advanced Materials 2001, 13(18):1351-1362; K. B, Jirage, C. R. Martin, “New developments in membrane-based separations”, Trends in Biotechnology 1999, 17(5):197-200).

Recently, a method for generating polymer membranes with uniform sub-1-nm pores was developed by cross-linking amphiphilic monomers in the type I bicontinuous cubic (Q_{I}) lyotropic liquid crystal (LLC) phase with retention of phase microstructure (D. L. Gin, J. E. Bara, R. D. Noble, B. J. Elliott, “Polymerized lyotropic liquid crystal assemblies for membrane applications”, Macromolecular Rapid Communications 2008, 29(5):367-389; M. J. Zhou, T. J. Kidd, R, D. Noble, D. L. Gin, “Supported lyotropic liquid-crystal polymer membranes: Promising materials for molecular-size-selective aqueous nanofiltration”, Advanced Materials 2005, 17 (15):1850-1853; M. J. Ihou, P. R. Nemade, X. Y. Lu, X. H, Zen, E. S. Hatakeyatna, R. D. Noble, D. L. Gin, “New type of membrane material for water desalination based on a cross-linked bicontinuous cubic lyotropic liquid crystal assembly”, Journal of the American Chemical Society 2007, 129(30:9574-9575). LLCs are molecules including a polar head group and a hydrocarbon tail. The amphiphilic character of these molecules encourages them to self-organize into aggregate structures in water, with the tails forming hydrophobic regions and the hydrophilic headgroups defining the interfaces of phase-separated aqueous domains. Cross-linked Q_{I} LLC phases with three-dimensionally interconnected porous structure and an effective pore size of 0.75 nm have recently been shown to operate as novel, nanoporous polymer membrane materials for effective water desalination (M. J. Ihou, P. R. Nemade, X. Y. Lu, X. H. leng, E. S. Hatakeyama, R. D. Noble, D. L. Gin, “New type of membrane material for water desalination based on a crosslinked bicontinuous cubic lyotropic liquid crystal assembly”, Journal of the American Chemical Society 2007, 129(31):9574-9575).

However, the effective pore size of 0.75 nm in these Q_{I}-phase LLC polymer membranes (FIG. 1) is not small enough for light gas separations via size discrimination, since light gases have kinetic diameters less than 0.4 nm, and their size differences are within a fraction of 0.1 nm. Additionally, there is also a need to make polymeric water NF membranes with controllable, uniform pore sizes below 0.75 nm to allow even finer size-based separations of smaller water-soluble ions (e.g., H⁺(aq): hydrated diameter=0.56 nm; K⁺(aq): hydrated diameter=0.66 nm) (E. R. Nightingale, “Phenomenological theory of ion solution—effective radii of hydrogen ions”, Journal of Physical Chemistry 1959, 63(9):1381-1387).

There is a need in the art for novel membranes with high levels of pore size uniformity, which allow substrate separation via size discrimination. These membranes would be useful for a variety of separation processes, including gas-phase and liquid-phase separations. The present invention meets this need.

### BRIEF SUMMARY OF THE INVENTION

The invention includes a composition comprising a nanoporous lyotropic liquid crystal (LLC) polymer membrane, wherein the LLC polymer membrane comprises a LLC polymer comprising at least one pore, wherein an inorganic material is attached to the interior surface of the at least one pore, and wherein the effective size of the at least one pore is less than 0.75 nm.

In one embodiment, the inorganic material is deposited inside the at least one pore using atomic layer deposition, In another embodiment, the inorganic material comprises an oxide. In yet another embodiment, the oxide comprises at least one compound selected from the group consisting of alumina, titania, silica, zinc oxide, and a combination thereof. In yet another embodiment, the at least one pore has a structure selected from the group consisting of type I bicontinuous cubic (Q_{I}) LLC phase structure, and inverted hexagonal (H_{II}) LLC phase structure. In yet another embodiment, the LLC polymer is formed by polymerization of at least one polymerizable LLC monomer selected from the group consisting of monomer 1, monomer 1a, monomer 2, monomer 3, monomer 4, monomer 5, monomer 6, and a combination thereof. In yet another embodiment, the LLC polymer is embedded within a porous support membrane or deposited as a layer on the surface of a porous support membrane.

The invention also includes a method of preparing a nanoporous lyotropic liquid crystal (LLC) polymer membrane. The method comprises the step of providing a LLC polymer membrane, wherein the LLC polymer membrane comprises a LLC polymer comprising at least one pore. The method further comprises the step of depositing an inorganic material within the at least one pore, wherein the inorganic material is attached to the interior surface of the at least one pore, and, wherein upon depositing of the inorganic material the effective size of the at least one pore is less than 0.75 nm; thereby forming the nanoporous LLC polymer membrane.

In one embodiment, the depositing is performed using atomic layer deposition. In another embodiment, the inorganic material comprises at least one oxide selected from the group consisting of alumina, titania, silica, zinc oxide, and a combination thereof. In yet another embodiment, the at least one pore has a structure selected from the group consisting of type I bicontinuous cubic (Q_{I}) LLC phase structure, and inverted hexagonal (H_{II}) LLC phase structure. In yet another embodiment, the LLC polymer is formed by polymerization of at least one polymerizable LLC monomer selected from the group consisting of monomer 1, monomer 1a, monomer 2, monomer 3, monomer 4, monomer 5, monomer 6, and a combination thereof. In yet another embodiment, the LLC polymer is embedded within a porous support membrane or deposited as a layer on the surface of a porous support membrane.

The invention also includes a method of performing size-selective separation of a given component in a fluid mixture. The method comprises the step of providing the fluid mixture comprising the given component. The method further comprises the step of contacting the fluid mixture with one surface of a nanoporous lyotropic liquid crystal (LLC) polymer membrane, wherein the LLC polymer membrane comprises a LLC polymer comprising at least one pore, wherein an inorganic material is attached to the interior surface of the at least one pore, and, wherein the effective size of the at least one pore is less than 0.75 nm. The method further comprises the step of applying a pressure difference across the nanoporous LLC polymer membrane. The method further comprises the step of isolating a filtered composition from the opposite surface of the LLC polymer membrane, wherein the ratio of the given component in the filtered composition is distinct from the ratio of the given component in the fluid mixture, thereby performing the separation of the given component.

In one embodiment, the effective diameter of the at least one pore is lower than the kinetic diameter of the given component. In another embodiment, the inorganic material comprises at least one oxide selected from the group consisting of alumina, titania, silica, zinc oxide, and a combination thereof. In yet another embodiment, the at least one pore has a structure selected from the group consisting of type I bicontinuous cubic (Q_{I}) LLC phase structure, and inverted hexagonal (H_{II}) LLC phase structure. In yet another embodiment, the LLC polymer is formed by polymerization of at least one polymerizable LLC monomer selected from the group consisting of monomer 1, monomer 1a, monomer 2, monomer 3, monomer 4, monomer 5, monomer 6, and a combination thereof. In yet another embodiment, the LLC polymer is embedded within a porous support membrane or deposited as a layer on the surface of a porous support membrane. In yet another embodiment, the fluid mixture is a gas or a liquid.

### BRIEF DESCRIPTION OF THE FIGURES

For the purpose of illustrating the invention, there are depicted in the drawings certain embodiments of the invention. However, the invention is not limited to the precise arrangements and instrumentalities of the embodiments depicted in the drawings.

FIG. 1 is a schematic representation of the structure of a cross-linked Q_{I}-phase, and of an alumina ALD modified Q_{I}-phase LLC polymer membrane.

FIG. 2 is a non-limiting illustration of a supported Q_{I}-phase LLC polymer membrane.

FIG. 3 is a graph illustrating powder XRD patterns of Q_{I}-phase LLC polymer membranes after different numbers of alumina ALD coating cycles.

FIG. 4 is a graph illustrating the (surface) element contents of the LLC polymer membranes with different cycles of alumina ALD coating based on XPS analysis.

FIG. 5 is a set of bar graphs illustrating permeance and selectivity of ALD-Q_{I}-phase LLC polymer membranes for different gases. Selectivity was given as the permeance of H₂ divided by that of the other gases.

### DETAILED DESCRIPTION OF THE INVENTION

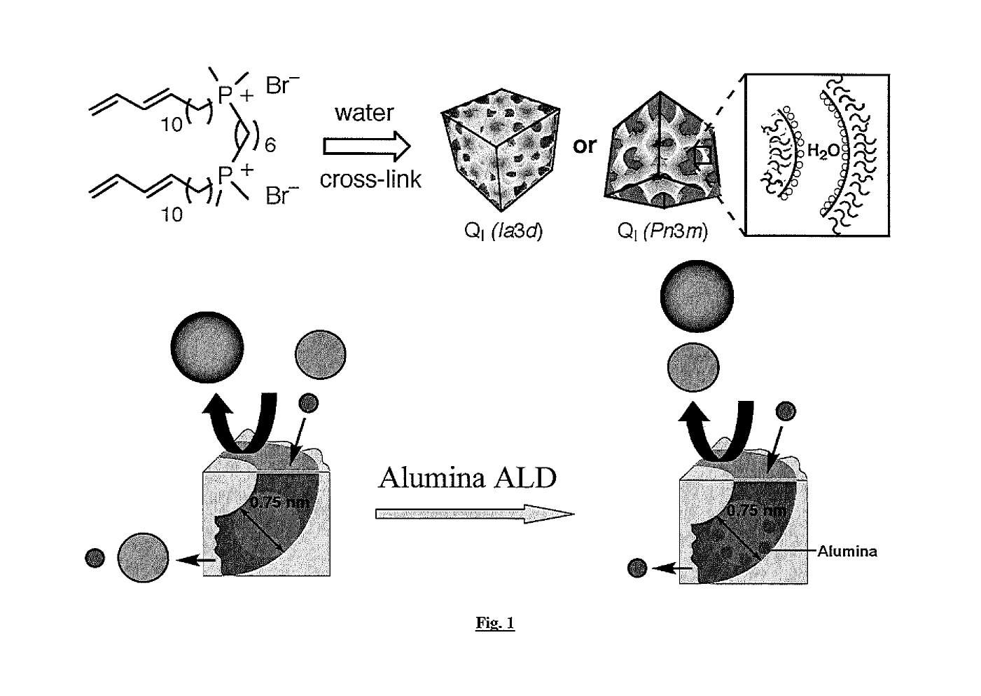

The invention relates to the unexpected discovery of nanoporous LLC polymer membranes, wherein ultra-thin films or clusters of inorganic material (e.g., ceramics such as alumina and titania) are deposited inside the porous structure of the LLC polymer membrane by atomic layer deposition (ALD), as schematically illustrated in FIG. 1. The modified membranes of the invention have high levels of pore size uniformity, based on the good pore size uniformity of the LLC polymer membranes, thereby allowing good separation via size discrimination. The modified membranes of the invention may be used for a variety of separation processes, including gas-phase and liquid-phase separations.

### DEFINITIONS

As used herein, each of the following terms has the meaning associated with it in this section.

As used herein, unless defined otherwise, all technical and scientific terms generally have the same meaning as commonly understood by one of ordinary skill in the art to which this invention belongs. Generally, the nomenclature used herein and the laboratory procedures in cell culture, molecular genetics, organic chemistry, and peptide chemistry are those well-known and commonly employed in the art.

As used herein, the articles “a” and “an” refer to one or to more than one (i.e. to at least one) of the grammatical object of the article. By way of example, “an element” means one element or more than one element.

As used herein, the term “about” will be understood by persons of ordinary skill in the art and will vary to some extent on the context in which it is used. As used herein, “about” when referring to a measurable value such as an amount, a temporal duration, and the like, is meant to encompass variations of ±20% or ±10%, more preferably ±5%, even more preferably ±1%, and still more preferably ±0.1% from the specified value, as such variations are appropriate to perform the disclosed methods.

As used herein, the term “comprising” includes “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements.

As used herein, the term “polymer” refers to a molecule composed of repeating structural units typically connected by covalent chemical bonds. The term “polymer” is also meant to include the terms copolymer and oligomers.

As used herein, the term “polymerization” refers to at least one reaction that consumes at least one functional group in a monomeric molecule (or monomer), oligomeric molecule (or oligomer) or polymeric molecule (or polymer), to create at least one chemical linkage between at least two distinct molecules (e.g., intermolecular bond), at least one chemical linkage within the same molecule (e.g., intramolecular bond), or any combination thereof. A polymerization reaction may consume between about 0% and about 100% of the at least one functional group available in the system. In one embodiment, polymerization of at least one functional group results in about 100% consumption of the at least one functional group. In another embodiment, polymerization of at least one functional group results in less than about 100% consumption of the at least one functional group.

As used herein, an “LLC polymer” or “LLC polymer composition” comprises polymerized lyotropic liquid crystal monomers in an ordered assembly. The LLC polymer composition may also comprise an initiator and/or a cross-linking agent. A porous LLC polymer is formed when the ordered assembly comprises pores or channels of solvent surrounded by the LLC monomers, and the resulting assembly is covalently linked together with preservation of the LLC phase structure. In one embodiment, the LLC polymer does not comprise functional groups such as halogen (unless as a counterion for maintaining overall charge neutrality with a cationic LLC polymer), hydroxyl, carbonyl, carboxylic acid, primary amine, or secondary amine. These functional groups provide sites at which it is possible to form chemical bonds during the ALD process.

As used herein, “LLC monomers” are polymerizable amphiphilic molecules that spontaneously self-assemble into fluid, yet highly ordered matrices with regular geometries of nanometer scale dimension when combined with water or another suitable polar organic solvent. LLC mesogens are amphiphilic molecules comprising one or more hydrophobic organic tails and a hydrophilic headgroup. In one embodiment, the headgroup is ionic.

As used herein, a “polymerizable LLC monomer” comprises a polymerizable group which allows covalent bonding of the monomer to another molecule such as another monomer, polymer or crosslinking agent. When the polymerizable group is attached to or part of the organic tail, the organic tails may be linked together during polymerization. Suitable polymerizable groups include acrylate, methacrylate, diene, vinyl, (halovinyl), styrenes, vinylether, hydroxy groups, epoxy or other oxiranes (halooxirane), dienoyls, diacetylenes, styrenes, terminal olefins, isocyanides, acrylamides, and cinamoyl groups. In one embodiment, the polymerizable group is an acrylate, methacrylate, or diene group.

As used herein, a “monodisperse” pore size has a variation in pore size from one pore to another of less than ca. 15% (specifically, an ideally narrow Poisson distribution). For pore manifold systems formed by some LLC phases (e.g., bicontinuous cubic phases), the pore size of a given pore varies along the pore channel. For pores which dimensions vary along the pore channel, a comparison of pore sizes is made at equivalent positions along the channel. In one embodiment, the pore size is mono-disperse when measured in this way. In one embodiment, the pore size may be measured by its minimum dimension. In one embodiment, the effective pore size of the structure may be determined by the size of the solute that can be excluded from the pore manifold.

As used herein, a “membrane” is a barrier separating two fluids that allows transport between the fluids. Porous LLC polymer membranes useful for the invention comprise a porous LLC polymer. In one embodiment, the membrane to be modified is a “composite” membrane comprising a porous LLC polymer composition combined with a porous support. In one embodiment, the porous LLC polymer membrane is a nanoporous membrane.

As used herein, the term “nanoporous” refers to a pore size between about 0.5 and about 6 nm in diameter, and a “nanofiltration membrane” has an effective pore size between about 0.5 and about 6 nm. For composite nanofiltration membranes, the LLC polymer portion of the composite may be nanoporous while the porous support has a larger average pore size. In one embodiment, the unmodified LLC polymer composition has an effective pore size between about 0.5 and 5.0 nm. In other embodiments the effective pore size greater than or equal to 0.5 to less than 2 nm, from 0.5 to 1 nm, or less than 1 nm.

As used herein, the term “electromagnetic radiation” includes radiation of one or more frequencies encompassed within the electromagnetic spectrum. Non-limiting examples of electromagnetic radiation comprise gamma radiation, X-ray radiation, UV radiation, visible radiation, infrared radiation, microwave radiation, radio waves, and electron beam (e-beam) radiation. In one aspect, electromagnetic radiation comprises ultraviolet radiation (wavelength from about 10 nm to about 400 nm), visible radiation (wavelength from about 400 nm to about 750 nm) or infrared radiation (radiation wavelength from about 750 nm to about 300,000 nm). Ultraviolet or UV light as described herein includes UVA light, which generally has wavelengths between about 320 and about 400 nm, UVB light, which generally has wavelengths between about 290 nm and about 320 nm, and UVC light, which generally has wavelengths between about 200 nm and about 290 nm, UV light may include UVA, UVB, or UVC light alone or in combination with other type of UV light. In one embodiment, the UV light source emits light between about 350 nm and about 400 nm. In some embodiments, the UV light source emits light between about 400 nm and about 500 nm.

As used herein, the term “Type (I) photoinitiator” refers to a compound that undergoes a unimolecular bond cleavage upon irradiation to yield free radicals. Non-limiting examples of Type (1) photoinitiators are benzoin ethers, benzyl ketals, α-dialkoxy-acetophenones, α-hydroxy-alkylphenones, α-amino-alkylphenones and acyl-phosphine oxides.

As used herein, the term “Type (II) photoinitiator” refers to a combination of compounds that undergo a bimolecular reaction where the excited state of the photoinitiator interacts with a second molecule (often known as “co-initiator”) to generate free radicals.

As used herein, the term “instructional material” includes a publication, a recording, a diagram, or any other medium of expression that may be used to communicate the usefulness of the compositions of the invention. In one embodiment, the instructional material may be part of a kit useful for generating a system of the invention. The instructional material of the kit may, for example, be affixed to a container that contains the compositions of the invention or be shipped together with a container that contains the compositions. Alternatively, the instructional material may be shipped separately from the container with the intention that the recipient uses the instructional material and the compositions cooperatively. For example, the instructional material is for use of a kit; instructions for use of the compositions; or instructions for use of a formulation of the compositions.

Throughout this disclosure, various aspects of the invention may be presented in a range format. It should be understood that the description in range format is merely for convenience and brevity and should not be construed as an inflexible limitation on the scope of the invention. Accordingly, the description of a range should be considered to have specifically disclosed all the possible sub-ranges as well as individual numerical values within that range and, when appropriate, partial integers of the numerical values within ranges. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

### Disclosure

The invention includes a nanoporous LLC polymer membrane, wherein ultra-thin films or clusters of inorganic material (e.g., ceramics such as alumina and titania) are deposited inside the porous structure of the LLC polymer membrane by atomic layer deposition (ALD). Post-treatments by surface film deposition can change the effective pore size and adsorption properties of the LLC polymer membranes. The excellent pore size uniformity of LLC polymer membranes can allow high levels of pore size uniformity to be obtained in the modified membranes, thereby allowing good separation via size discrimination. The modified membranes of the invention can be used for a variety of separation processes, including gas-phase and liquid-phase separations.

In one aspect, the invention includes a modified porous LLC polymer membrane which comprises inorganic material attached to the surface of the pores inside the membrane. In one embodiment, the inorganic material is an oxide. The inorganic material may form a continuous or discontinuous layer. The pores of the LLC polymer membrane may be interconnected or not prior to ALD deposition. In one embodiment, the porous LLC polymer membrane has a pore structure of interconnected nanopores based on the type I (normal type) bicontinuous cubic (Q_{I}) LLC phase structure. In different embodiments, the effective pore size of the modified membrane is less than 0.75 nm, less than 0.7 nm, less than 0.65 nm, less than 0.6 nm, less than 0.55 nm, less than 0.5 nm, or less than 0.45 nm. In one embodiment, the effective pore size of the structure may be determined by the size of the solute or gas molecule that can be excluded from the membrane.

It is possible in some instances to perform a precursor reaction to introduce desirable functional groups onto the surface of the polymer substrate. Depending on the particular polymer, techniques such as water plasma treatment, ozone treatment, ammonia treatment and hydrogen treatment are among the useful methods of introducing functional groups.

The polymer may be treated before initiating the reaction sequence to remove volatile materials that may be absorbed onto the surface. This is readily done by exposing the substrate to elevated temperatures and/or vacuum. The polymer substrate is then sequentially contacted with gaseous reactants used to form the inorganic material. In one embodiment, the reactions are performed at a temperature below that at which the organic polymer degrades, melts, or softens enough to lose its physical shape. The temperature at which the ALD reactions are conducted is generally below 550 K. In one embodiment, the temperature may be below 500 K, below 450 K, below 400 K, below 375 K, or below 350 K, with the upper temperature limit being dependent on the particular organic polymer to be coated. The reactants are gases at the temperature the reactions are conducted. Particularly preferred reactants have vapor pressures of at least 10 mtorr, more preferably at least 100 mtorr, and even more preferably at least 1 torr or greater at a temperature of 300 K. In addition, the reactants are selected such that they can engage in the reactions that form the inorganic material at the temperatures stated above. Catalysts may be used to promote the reactions at the required temperatures.

The membrane is generally held in a chamber that can be evacuated to low pressures. Each reactant is introduced sequentially into the reaction zone in a sequence of dosing steps, typically together with an inert carrier gas. Before the next reactant is introduced, the reaction by-products and unreached reagents are removed in a purging step. This can be done, for example, by subjecting the substrate to a high vacuum, such as about 10⁻⁵ torr or lower, after each reaction step. Another method of accomplishing this, which is more readily applicable for industrial application, is to sweep the substrate with an inert purge gas between the reaction steps. This purge gas can also act as a carrier for the reagents. The next reactant is then introduced, where it reacts at the surface of the substrate. By removing excess reagents and reaction by-products, as before, the reaction sequence can be repeated as needed to build inorganic deposits of the desired size or thickness.

During the ALD process, the dose time for a given reactant is selected to be sufficiently long to allow the desired extent of penetration of the reactant into the pores of the membrane. In one embodiment, the dose time is 30 s to 300 s. Similarly, the purge time is selected to be sufficiently long to allow removal of excess reactant. In one embodiment, the purge time is 1800 s to 7200 s. General methods for conducting ALD processes are described, for example, in J. W. Klaus et al, “Atomic Layer Controlled Growth of Si02 Films Using Binary Reaction Sequence Chemistry”, Appl. Phys. Let. 1997, 70:1092 and O, Shah et al., “Atomic Layer Growth of SiO₂ on Si (100) and H₂O using a Binary Reaction Sequence”, Surface Science 1995, 334:135.

The selection of reactants may be important in obtaining good adhesion of the inorganic material. If the polymer does not have functional groups that provide sites at which it is possible to form chemical bonds between the polymer and the inorganic material, at least one of the reactants may be selected so that it will “wet” the surface of the polymer substrate. In one embodiment, if the reagent is contacted in bulk with a non-porous substrate of the polymer, it will tend to penetrate into small pores or other imperfections in the surface of the polymer substrate (a “wetting” reactant) (PCT Publication No. WO 03/008110; Ferguson, J. D., A. W. Weimer, and S. M. George, “Atomic Layer Deposition of Al₂O₃ Films on Polyethylene Particles,” Chemistry of Materials 2004, 16 (26):5602-5609).

If the polymer substrate contains functional groups, the first reactant may also be reactive with those functional groups at the reaction temperatures described before, thereby forming a surface species that is chemically bonded to the polymer and capable of engaging in further reactions to form the inorganic material.

Trimethylaluminum (TMA) is sorbed well onto a wide variety of polymer substrates. TMA ALD reactions usually form alumina (Al₂O₃). An illustrative example of an overall reaction of this type is 2Al(CH₃)₃+3H₂O→Al₂O₃+6CH₄. In the ALD process, this reaction is via alternating exposure to TMA and water. The minimum effective pore size that may be obtained in the modified membrane may depend upon the effective size of the ALD reactants.

Many ALD reaction sequences do not include a good wetting reactant. It is still possible in such cases to deposit the desired inorganic material onto the polymer. One way of accomplishing this is to deposit a “precursor” inorganic material onto the substrate, via an ALD reaction sequence that includes a good wetting reactant. Reactive species on the precursor inorganic material can become reactive sites at which a second ALD sequence can be initiated to deposit the desired inorganic material. A particularly suitable “precursor” inorganic material is alumina, which is preferably deposited as described above. As few as two repetitions of a reaction cycle forming a “precursor” inorganic material can be used. A preferred number of reaction cycles to deposit a “precursor” inorganic material is from 2 to about 200 cycles, especially from about 5 to about 25 reaction cycles.

Since TMA can be effective at wetting polymers, in one embodiment it is desirable to use TMA to deposit an Al₂O₃ ALD film on the polymer surface and to place TiO₂, SiO₂, ZnO, or other ALD film on top of the Al₂O₃ film, whereby the top most layer provide suitable chemical compatibility with the matrix fluid used in the separation process.

In one embodiment, the inorganic material is an oxide. In one embodiment, the inorganic material is other than a metal. In a different embodiment, the inorganic material may be alumina, titanic, silica, or zinc oxide.

The inorganic deposits formed in the ALD process may take the form of individual particles, or a continuous or semi-continuous film. The physical form of the deposits depends on factors such as the physical form of the polymer and the number of times the reaction sequence is repeated. It has been found that the inorganic material formed in the first one or several reaction sequences tends to be deposited discontinuously. As the reaction sequences are continued, the initially discontinuous deposits often becomes interconnected as further inorganic material is deposited.

Different porous architectures can be achieved via the use of LLC monomers that form different mesophases in a solvent. Depending on where they appear on the phase diagram relative to the central lamellar (La) phase, these phases can be classified as Type I (oil-in-water or normal) or Type II (water-in-oil or inverted). In one embodiment, the pores of the mesophase are filled with the solvent, the solvent being a polar liquid such as water or an aqueous solution. In this one embodiment, the hydrophilic headgroups of the LLC mesogens are oriented towards the pores of the mesophase, “lining” the pores. The LLC phase structure may be a polydomain structure, and therefore may display short-range rather than long-range order.

A small number of non-aqueous solvent-based LLC systems are known in the literature. These water-free LLC phases are formed around organic solvents such as ethylene glycol, glycerol, formamide, N-methylformamide, dimethylformamide, N-methylsydnone, (Auvray, X.; Perche, T.; Petipas, C.; Anthore, R. Langmuir 1992, 8:2671, and references therein), and some imidazolium-based room-temperature ionic liquids (RTILs) (Greaves, T. L.; Drummond, C. J. Chem. Soc. Rev. 2008, 37:1709), instead of water. In another embodiment, ALD modification may be applied to polymerized LLC films based on non-aqueous solvents.

LLC monomers useful for the present invention may be polymerized into a crosslinked network with substantial retention of the original LLC phase microstructure. In some LLC phases, contraction of the structure is observed on heavy crosslinking of the polymer into a network. Expansion of Q_{I} unit cells has been observed for some LLC monomers (Pindzola, B. A.; Jin, J.; Gin, D. L. “Crosslinked Normal Hexagonal and Bicontinuous Cubic Assemblies via Polymerizable Gemini Amphiphiles,” J. Am. Chem. Soc. 2003, 125 (10):2940-2949). Some disordering of the phases may also be observed upon cross-linking, as evidenced by a loss in X-ray diffraction (XRD) peak intensity.

In one embodiment, the pore structure after polymerization is substantially determined or controlled by the Q phase which is formed by the monomers. In this case the pore structure may be based on the bicontinuous cubic LLC structure. The pore structure after polymerization need not be identical to that of the bicontinuous cubic LLC phase. In one embodiment, the pore structure of the polymerized network retains at least part of the bicontinuous cubic phase structure and comprises interconnected, ordered 3-D nanopores. Retention of the bicontinuous cubic phase structure may be confirmed through observation of XRO peaks characteristic of the structure.

In one embodiment, the LLC polymer has a pore structure of interconnected nanopores. For example, polymerizable LLC phases with bicontinuous cubic (Q) architectures have interconnected 3-D nanochannels. These phases are termed bicontinuous because they have two or more unconnected but interpenetrating hydrophobic and/or solvent networks with overall cubic symmetry. In this case, the polymerized network has a pore structure of interconnected, ordered 3-D nanopores. The pore structure is substantially determined or controlled by the bicontinuous cubic phase which was formed by the monomers. In one embodiment, the LLC polymer composition has a pore structure of interconnected nanopores based on the type I (normal type) bicontinuous cubic (Q_{I}) LLC phase structure. For Q, phases, the size of the gap between the organic portions of the structure determines the effective pore size of the structure.

Several polymerizable LLCs are known to spontaneously form type I bicontinuous cubic (Q_{I}) LC phases. These mesogens include gemini surfactant monomers. Monomer 1 forms a bicontinuous cubic phase (Pindzola, B. A., Ph.D. Thesis (2001), University of California, Berkeley). In one embodiment, the spacer and tail length of the gemini surfactant are “matched”, with larger spacer lengths corresponding to longer tail lengths. In different embodiments, x is 8, 10 or 14 and y is 2, 4 or 6; y=2 and x=10; y=6 and x=10, y=8 and x=10, y=8 and x=14.

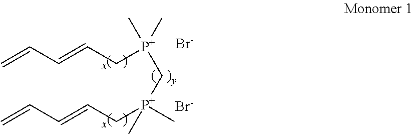

Polymerizable gemini cationic imidazolium surfactants based on room temperature ionic liquids (RTILs) have also, been developed and are described in U.S. Patent Application Publication No. US 2008/0029735, which is hereby incorporated by reference. These surfactants can form bicontinuous cubic (Q) phases when mixed with water or room temperature ionic liquids.

In one embodiment, the polymerizable gemini imidazolium surfactant composition is Monomer 1a:

[(P-Y)-H-L-H-(Y-P)]²⁺.(2/n)[Xⁿ⁻] (Monomer 1a)

wherein:

H is a hydrophilic head group comprising a five membered cationic aromatic ring containing two nitrogens (e.g., an imidazolium ring);

X is an anion of negative charge n,

L is a spacer or linking group which connects the two headgroup rings, and

Y is a hydrophobic tail group attached to each ring and having at least 10 carbon atoms and comprising a polymerizable group P.

Each spacer L is attached to a first nitrogen atom in each of the two linked rings. The attachment may be through a covalent or a noncovalent bond, such as an ionic linkage. Each hydrophobic tail group Y is attached to the second (other, non-bridged) nitrogen atom in each ring. The combination of the hydrophilic head group H, the linker L, and the hydrophobic tail Y form an imidazolium cation.

Monomer 2 is an imidazolium-based polymerizable gemini surfactant that forms Q LLC phases with RTILs and water as the polar solvent. In one embodiment, in in the tail is from 0 to 10 and headgroup linker L=(CH₂)ₓ with x ranges from 1 to 12 or L=((CH₂)₂O)_{y}(CH₂)₂, and y ranges from 1 to 6. In other embodiments, in is 0 to 6 or 3-7.

In one embodiment, the anion present in the surfactant or monomer, X, is a standard anion used in preparing RTILs. These anions include, but are not limited to Br⁻, BE₄⁻, Cl⁻, I⁻, CF₃SO₃⁻, Tf₂N⁻ (and other large fluorinated anions), PF₆⁻, DCA⁻, MeSO₃⁻, and TsO⁻. In one embodiment, the anion X⁻ is selected from the group consisting of Br⁻ and BF₄⁻. It is believed that amphiphile anions that are simple halogen ions (e.g., Br⁻) are generally suitable for use with aqueous solvents, but may not be as suitable for use with some RTILs.

Suitable polymerizable groups include acrylate, methacrylate, diene, vinyl, (halovinyl), styrenes, vinylether, hydroxy groups, epoxy or other oxiranes (halooxirane), dienoyls, diacetylenes, styrenes, terminal olefins, isocyanides, acrylamides, and cinnamoyl groups. In one embodiment, the polymerizable group is an acrylate, methacrylate or diene group. In another embodiment, the polymerizable group is an acrylate group. The tail group may have some portions that are more hydrophobic than others (e.g., if the tail contains a polymerizable group attached to an alkyl chain), but the tail group is overall hydrophobic with respect to the headgroup portion of the molecule.

In another embodiment, surfactants that form the Q phase have L=(CH₂)ₓ, x=6, and X⁻=BF₄⁻. Surfactants that form the Q LLC phase also can have L=((CH₂)₂O)_{y}(CH₂)₂ and y=1 or 2, X⁻=halide ion (e.g., Br⁻ and m=3-7). In one embodiment, L=((CH₂)₂O)_{y}(CH₂)₂ with y=1, X⁻=Br, m=5, and PG=1,3-diene illustrated as monomer 2,

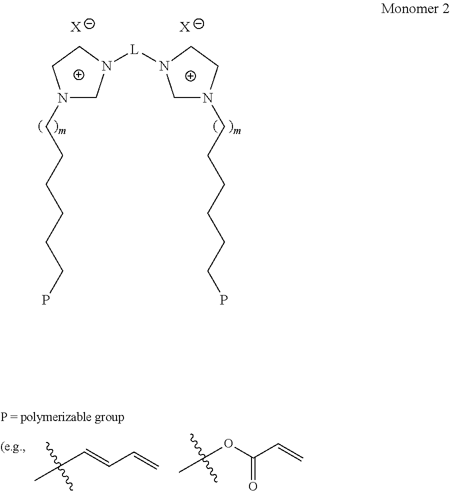

Polymerizable LLCs (i.e., cross-linkable surfactants) have also been designed that spontaneously form the inverted hexagonal (H_{II}) LLC phase in the presence of a small amount of water. Upon photopolymerization or photo-cross-linking, robust polymer networks containing hexagonally packed, extended water channels with monodisperse diameters of nanometer-scale dimensions are produced. The network has a pore structure of hexagonally ordered, cylindrical nanopores. The pore structure is substantially determined or controlled by the inverted hexagonal phase which was formed by the monomers. In one embodiment, the LLC polymer composition has a pore structure of nanopores based on the type II (inverted) hexagonal structure. Polymerizable LLCs may also form lamellar phases. H_{II}-phase forming monomers are typically taper-shaped molecules, and some examples (monomers 3-6) are shown below.

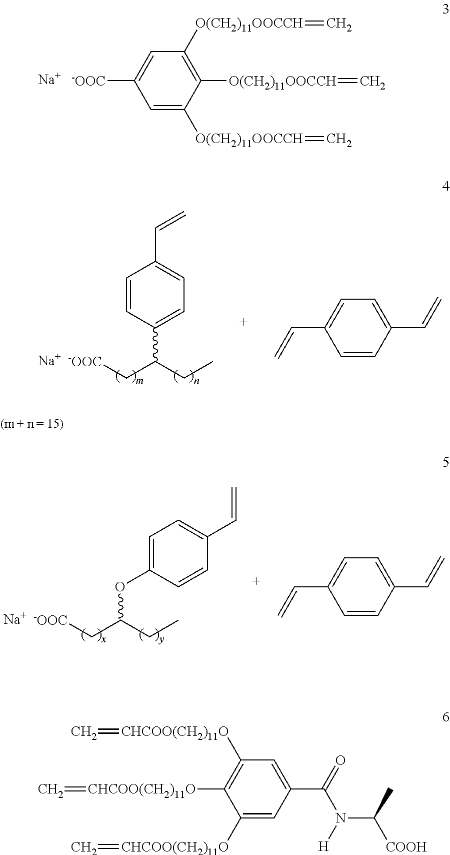

In one embodiment, the pores of the as-synthesized LLC polymer composition may be filled with water, an aqueous solution, or some other polar liquid. In one embodiment, the pores of the LLC polymer composition may be filled with the polar liquid by using this liquid as the solvent in the LLC mixture. Prior to ALD deposition, a pre-treatment step may be used to remove solvent from the pores. However, some residual solvent may remain following the pretreatment step.

In one embodiment, the porous LLC polymer composition is embedded within a porous support membrane, thereby forming a composite membrane. In this embodiment, the composite membrane may be surface modified by atomic layer deposition, with inorganic material being deposited within the pores of the porous LLC polymer. In the portions of the support containing the LLC polymer composition, the LLC polymer composition fills enough of the support pore space, so that separation process is controlled by the pores of the LLC polymer composition. In one embodiment, there is no “non-LLC” pore with a pore size greater than that of the LLC polymer composition that traverses the composite membrane. In one embodiment, the LLC polymer composition is present throughout the thickness of the support, so that the thickness of the composite membrane may be taken as the thickness of the support. During fabrication of the composite membrane, the LLC mixture may be applied to only a portion of the surface of the support. The LLC polymer composition may be retained within the support by mechanical interlocking of the LLC polymer composition with the support.

In one embodiment, the membrane to be modified comprises a porous support, and a porous LLC polymer composition attached to the support. The LLC polymer composition has a pore structure of interconnected nanopores based on the type I (normal type) bicontinuous cubic (Q_{I}) LLC phase structure. In one embodiment, the LLC polymer composition comprises a polymer network formed from polymerizable LLC monomers and optional cross-linking agents. In one embodiment, the LLC polymer composition is formed by polymerization of an LLC mixture which forms the type I (normal type) bicontinuous cubic LLC phase, the LLC mixture comprising polymerizable LLC monomers and a solvent and not including a hydrophobic polymer, the LLC polymer composition comprising a pore structure of interconnected nanopores based on the type I bicontinuous cubic LLC structure. The polymerizable LLC monomers are assembled in the type I (normal type) bicontinuous phase prior to polymerization.

In another embodiment, the LLC polymer composition forms a layer on the surface of the support; this layer acts as a membrane. In different embodiments, the thickness of this layer is less than 10 microns, less than 5 microns, less than 2 microns, less than 1 micron, or less than 0.5 microns.

In one embodiment, the porous support is hydrophilic. As used herein, a hydrophilic support is wettable by water and capable of spontaneously absorbing water. The hydrophilic nature of the support may be measured by various methods known to those skilled in the art, including measurement of the contact angle of a drop of water placed on the membrane surface, the water absorbency (weight of water absorbed relative to the total weight, U.S. Pat. No. 4,720,343) and the wicking speed (U.S. Pat. No. 7,125,493). The observed macroscopic contact angle of a drop of water placed on the membrane surface may change with time. In different embodiments, the contact angle of a 2 μL drop of water placed on the support surface (measured within 30 seconds) is less than about 90 degrees, from about 5 degrees to about 85 degrees, about zero degrees to about 30 degrees or is about 70 degrees. In another embodiment, the membrane is fully wetted by water and soaks all the way through the membrane after about one minute. Hydrophilic polymeric supports include supports formed of hydrophilic polymers and supports which have been modified to make them hydrophilic. In another embodiment, the support is hydrophobic.

Typically, the porous support membrane has a smaller flow resistance than the LLC membrane. In one embodiment, the porous support in this system is selected so that the diameter of the pores is less than about 10 microns and greater than the effective pore size of the LLC polymer composition. In one embodiment, the support is microporous or ultraporous. In another embodiment, the support has a pore size less than about 0.1 micron or from 0.1 micron to 10 microns. The preferred pore size of the support may depend on the composition of the LLC mixture. The characteristic pore size of the membrane may depend on the method used to measure the pore size. Methods used in the art to determine the pore size of membranes include Scanning Electron Microscopy analysis, capillary flow porometry analysis (which gives a mean flow pore size), measurement of the bubble pressure (which gives the largest flow pore size), and porosimetry.

The porous support membrane can give physical strength to the composite structure. When the LLC polymer composition is somewhat brittle, the support membrane can also add flexibility to the composite membrane. The support should also be thermally stable over approximately the same temperature range as the LLC membranes to be used.

The support is selected to be compatible with the solution used for LLC membrane formation, as well as to be compatible with the liquid or gas to be filtered. When the solution used for LLC membrane fabrication and the support are compatible, the support is resistant to swelling and degradation by the solution used to cast the LLC polymer porous membrane. In one embodiment, the organic solvent used in the solution and the support are selected to be compatible so that the support is substantially resistant to swelling and degradation by the organic solvent, Swelling and/or degradation of the support by the solvent may lead to changes in the pore structure of the support. In one embodiment, if the membrane is to be used for water based separations, the porous support is sufficiently hydrophilic for water permeation.

The porous support may be made of any suitable material known to those skilled in the art including polymers, metals, and ceramics. In various embodiments, the porous polymer support comprises polyethylene (including high molecular weight and ultra high molecular weight polyethylene), polyacrylonitrile (PAN), polyacrylonitrile-co-polyacrylate, polyacrylonitrile-co-methylacrylate, polysulfone (PSf), Nylon 6,6, poly(vinylidene difluoride), or polycarbonate. In one embodiment, the support may be a polyethylene support or a support of another polymer mentioned above (which may include surface treatments to affect the wettability of the support). The support may also be an inorganic support such as a nanoporous alumina disc (Anopore J Whatman, Ann Arbor, Mich.). The porous support may also be a composite membrane.

In one embodiment, the solution used for applying the LLC monomer, also known as the “LLC mixture”, comprises a plurality of polymerizable LLC monomers, an aqueous or polar organic solvent, and a polymerization initiator. A single species of polymerizable LLC monomer may be used, but a plurality of monomers is required for phase formation. The aqueous or polar solvent is selected so that the LLC monomer forms the desired Q_{I} phase. Because of the LLC phase formation, the solution formed may not be uniform. The mixture components do not include the porous support. In one embodiment, suitable polar liquid solvents include, but are not limited to water, dimethylformamide, and THF or room temperature ionic liquids. In another embodiment, suitable polar organic solvents suitable as water substitutes for LLC assembly include ethylene glycol, glycerol, formamide, N-methylformamide, dimethylformamide, or N-methylsydnone, most of which are fairly water-miscible, protic organic solvents, with the exception of N-methylsydnone. RTILs are polar, molten organic salts under ambient conditions that are typically based on substituted imidazolium, phosphonium, ammonium, and related organic cations complemented by a relatively non-basic and non-nucleophilic large anion. In one embodiment, the solvent is aqueous. The polymerization initiator can be photolytically or thermally activated. The mixture is thoroughly combined. In one embodiment, mixing may be performed through a combination of hand mixing and centrifuging.

In one embodiment, the LLC mixture does not further comprise a hydrophobic polymer as described by Lu et al. (Lu, X.; Nguyen, V.; Zhou, M.; Zeng, X.; Jin, J.; Elliott, B. J.; Gin, D. L. “Cross-linked Bicontinuous Cubic Lyotropic Liquid Crystal-Butyl Rubber Composites: Highly Selective, Breathable Barrier Materials for Chemical Agent Protection,” Adv. Mater. 2006, 18(24):3294-3298) and U.S. Pat. No. 7,090,788).

The LLC mixture may further comprise an optional cross-linking agent molecule to help promote intermolecular bonding between polymer chains. The crosslinking agent is not required if the monomer can cross-link without a cross-linking agent. In one embodiment, the cross-linking agent is not a polymer. In one embodiment, the cross-linking agent has less than 10 monomeric repeat units and/or has a weight less than 500 Daltons. Typically, the cross-linking agent or curing agent is a small molecule or monomeric cross linker such as divinylbenzene (DVB). Cross-linking agents are known to those skilled in the art.

The amount of cross-linking agent is small enough to allow formation of the desired LLC phase. The cross-linker is typically hydrophobic, in order to dissolve in and help to cross-link the hydrophobic tail regions of the LLC phase. For water filtration applications, the incorporation of additional hydrophobic components into the LLC mixture may be limited to prevent the overall polymeric composition from being too hydrophobic for good water filtration. In one embodiment, the maximum amount of cross-linking agent is 10 wt % to 15 wt %. In another embodiment, when the cross-linking agent is hydrophobic, its size is kept small enough so that reduction of the overall density or surface coverage of the polar solvent (e.g., water) nanopores is limited.

The photoinitiator contemplated within the invention is a molecule that, upon irradiation with a given wavelength at a given intensity for a given period of time, generates at least one species capable of catalyzing, triggering or inducing a polymerization or crosslinking. A photoinitiator known in the art may be employed, such as a benzoin ether and a phenone derivative such as benzophenone or diethoxyacetophenone. In one embodiment, the irradiation comprises ultraviolet electromagnetic radiation (wavelength from about 10 nm to about 400 nm), visible electromagnetic radiation (wavelength from about 400 nm to about 750 nm) or infrared electromagnetic radiation (radiation wavelength from about 750 nm to about 300,000 nm). In another embodiment, the electromagnetic radiation comprises ultraviolet or visible electromagnetic radiation.

Ultraviolet or UV light as described herein includes UVA light, which generally has wavelengths between about 320 and about 400 nm, UVB light, which generally has wavelengths between about 290 nm and about 320 nm, and UVC light, which generally has wavelengths between about 200 mm and about 290 nm. UV light may include UVA, UVB, or UVC light alone or in combination with other type of UV light. In one embodiment, the UV light source emits light between about 350 nm and about 400 nm. In some embodiments, the UV light source emits light between about 400 nm and about 500 nm.

Non-limiting examples of the photoinitiator contemplated within the invention are:
1-hydroxy-cyclohexyl-phenyl-ketone (Irgacure™ 184; Ciba, Hawthorne, N.J.);
a 1:1 mixture of 1-hydroxy-cyclohexyl-phenyl-ketone and benzophenone (Irgacure™ 500; Ciba, Hawthorne, N.J.);
2-hydroxy-2-methyl-1-phenyl-1-propanone (Darocur™ 1173; Ciba, Hawthorne, N.J.);
2-hydroxy-1-[4-(2-hydroxyethoxy)phenyl]-2-methyl-1-propanone (Irgacure™ 2959; Ciba, Hawthorne, N.J.);
methyl benzoylformate (Darocur™ MBF; Ciba, Hawthorne, N.J.);
oxy-phenyl-acetic acid 2-[2-oxo-2-phenyl-acetoxy-ethoxy]-ethyl ester;
oxy-phenyl-acetic 2-[2-hydroxy-ethoxy]-ethyl ester;
a mixture of oxy-phenyl-acetic acid 2-[2-oxo-2-phenyl-acetoxy-ethoxy]-ethyl ester and oxy-phenyl-acetic 2-[2-hydroxy-ethoxy]-ethyl ester (Irgacure™ 754; Ciba, Hawthorne, N.J.);
alpha,alpha-dimethoxy-alpha-phenylacetophenone (Irgacure™ 651; Ciba, Hawthorne, N.J.);
2-benzyl-2-(dimethylamino)-1-[4-(4-morpholinyl)-phenyl]-1-butanone (Irgacure™ 369; Ciba, Hawthorne, N.J.);
2-methyl-1-[4-(methylthio)phenyl]-2-(4-morpholinyl)-1-propanone (Irgacure™ 907; Ciba, Hawthorne, N.J.);
a 3:7 mixture of 2-benzyl-2-(dimethylamino)-1-[4-(4-morpholinyl) phenyl]-1-butanone and alpha,alpha-dimethoxy-alpha-phenylacetophenone per weight (Irgacure™ 1300; Ciba, Hawthorne, N.J.);
diphenyl-(2,4,6-trimethylbenzoyl) phosphine oxide (Darocur™ TPO; Ciba, Hawthorne, N.J.);
a 1:1 mixture of diphenyl-(2,4,6-trimethylbenzoyl)-phosphine oxide and 2-hydroxy-2-methyl-1-phenyl-1-propanone (Darocur™ 4265; Ciba, Hawthorne, N.J.);
phenyl bis(2,4,6-trimethyl benzoyl) phosphine oxide, which may be used in pure form (Irgacure™ 819; Ciba, Hawthorne, N.J.) or dispersed in water (45% active, Irgacure™ 819DW; Ciba, Hawthorne, N.J.);
a 2:8 mixture of phosphine oxide, phenyl bis(2,4,6-trimethyl benzoyl) and 2-hydroxy-2-methyl-1-phenyl-1-propanone (Irgacure™ 2022; Ciba, Hawthorne, N.J.);
Irgacure™ 2100, which comprises phenyl-bis(2,4,6-trimethylbenzoyl)-phosphine oxide);
bis-(eta 5-2,4-cyclopentadien-1-yl)-bis-[2,6-difluoro-3-(1H-pyrrol-1-yl) phenyl]-titanium (Irgacure™ 784; Ciba, Hawthorne, N.J.);
(4-methylphenyl) [4-(2-methylpropyl) phenyl]-iodonium hexafluorophosphate (Irgacure™ 250; Ciba, Hawthorne, N.J.);
2-(4-methylbenzyl)-2-(dimethylamino)-1-(4-morpholinophenyl)-butan-1-one (Irgacure™ 379; Ciba, Hawthorne, N.J.);
4-(2-hydroxyethoxy)phenyl-(2-hydroxy-2-propyl)ketone (Irgacure™ 2959; Ciba, Hawthorne, N.J.);
bis-(2,6-dimethoxybenzoyl)-2,4,4-trimethylpentylphosphine oxide;
a mixture of bis-(2,6-dimethoxybenzoyl)-2,4,4-trimethylpentylphosphine oxide and 2-hydroxy-2-methyl-1-phenyl-propanone (Irgacure™ 1700; Ciba, Hawthorne, N.J.);
titanium dioxide; and mixtures thereof.

The photoinitator may be used in amounts ranging from about 0.01 to about 25 weight percent (wt %) of the composition, more preferably from about 0.1 to about 20 weight percent (wt %) of the composition, more preferably from about 1 to about 15 weight percent (wt %) of the composition, more preferably from about 2 to about 10 weight percent (wt %) of the composition.

The mixture may further comprise an organic solvent for formulation or delivery of the LLC monomer (e.g., for solvent casting). The solvent may be any low boiling point organic solvent that dissolves the monomer. A mixture of one or more solvents may also be used. Useful solvents include, but are not limited to, methanol and diethyl ether. In one embodiment, the monomer is dissolved in the organic solvent, and then the water and the optional cross-linking agent are added. In one embodiment, the organic solvent used in the solution and the support are selected to be compatible so that the support is substantially resistant to swelling and degradation by the organic solvent. Swelling and/or degradation of the support by the solvent can lead to changes in the pore structure of the support.

The composition of the LLC mixture may be selected to obtain the desired bicontinuous phase based on the phase diagram for the LLC monomer. For example, at atmospheric pressure the LLC phases present in the system may be determined as a function of temperature and percentage of amphiphile (LLC monomer) in the system. The percentage of LLC monomer in the mixture and the temperature may then be selected together to obtain the desired bicontinuous cubic phase. When the phase of LLC mixture is sensitive to the water or other solvent content, steps may be taken to minimize evaporative water or solvent loss during the membrane fabrication process.

In one embodiment, when the LLC monomer is monomer 1, the weight percent of water in the LLC mixture is from 5% to 15 wt %. Temperature control may be needed to maintain the phase during the photo-cross-linking after infiltration into the support membrane (i.e., ca. 70° C.). In another embodiment, the concentration of the imidazolium-based LLC surfactant or monomer is between 10% and 100%.

In one embodiment, the LLC mixture is assembled into the LLC phase before the mixture is contacted with the porous support. The mixture may be allowed to rest at room temperature or at any suitable temperature dictated by the phase diagram. Analysis of the LLC phases can be performed by several methods known to those skilled in the art including polarized light microscopy (PLM) and x-ray diffraction (XRD). Q phases are optically isotropic (have a black optical texture) when viewed with the PLM, XRD of Q phases exhibit symmetry-allowed d spacings that ideally proceed in the ratio 1:1/sqrt(2): 1/sqrt(3): 1/sqrt(4): 1/sqrt(5): 1/sqrt(6): 1/sqrt(8): 1/sqrt(9): 1/sqrt(10): and so forth, corresponding to the d₁₀₀, d₁₁₀, d₁₁₁, d₂₀₀, d₂₁₀, d₂₁₁, d₂₂₀, d₂₂₁ (or d₃₀₀), d₃₁₀, and so forth diffraction planes. The presence of Q phases with P or I symmetry in polydomain small molecule amphiphile and phase separated block copolymer systems has generally been identified on the basis of a black optical texture and a powder XRD profile in which the 1/sqrt(6): and 1/sqrt(8): d spacings (i.e., the d₂₁₁ and d₂₂₀ reflections) are at least present. The higher order XRD reflections may be used to distinguish between the different 3-D cubic phase architectures, since systematic XRD absences in the XRD peaks result as the cubic cells becomes more complex. However, the higher order reflections may not be observed when the phases do not possess a great deal of long range order. In one embodiment, the LLC mixture has a fluid gel-like consistency before cross-linking or polymerization.

In one embodiment where the LLC polymeric composition is embedded into the support, a quantity of the LLC mixture is placed on a surface of the porous support membrane and then infused into the porous support. In one aspect of the invention, the support is impregnated with the LLC mixture using a combination of heat and pressure to drive the LLC mixture into the pores of the support. The temperature and pressure are selected so that LLC phase is still retained. The LLC mixture and support may be heated to decrease the viscosity of the LLC mixture before pressure is applied. In one embodiment, a heated press may be used to impregnate the support with the LLC mixture. When a press is used, the LLC mixture and support membrane may be sandwiched between a pair of load transfer plates. Additionally, a pair of polymeric sheets may be used to facilitate release of the support mixture and membrane from the load transfer plates and limit evaporation of water from the mixture, Suitable dense polymeric sheets that are transparent to UV or visible light include, but are not limited to Mylar® (a biaxially-oriented polyester film made from ethylene glycol and dimethyl teraphthalate). The LLC mixture need not completely fill the pore space of the support, but fills enough of the pore space of the support so that separation process is controlled by the pores of the LLC polymer composition. In one embodiment, the gel is pushed uniformly through the entire support membrane thickness.

After impregnation of the support with the LLC mixture, the LLC monomers are then cross-linked to form the LLC polymer composition. In one embodiment, the LLC monomers are polymerized by cross-linking the hydrophobic tails. In one embodiment, the LLC phase can be photo-cross-linked by putting it under UV light in air or nitrogen at ambient temperature (or at the required temperature to maintain the desired LLC phase). Other temperatures as known by those skilled in the art may be used during the cross-linking process. Other methods of crosslinking as known to those skilled in the art may also be used. For example, thermal cross-linking may be performed using a cationic initiator as a cross-linking agent. The degree of cross-linking can be assessed with infrared (IR) spectroscopy. In different embodiment, the degree of polymerization is greater than 90% or greater than 95%. In other embodiments, the LLC polymer composition is formed as a thin, supported top-film on top of the support. In different embodiments, the coating of the LLC monomer mixture can be formed by solution-casting the LLC monomer mixture to make thin films on membrane supports after evaporation of the delivery solvent; doctor-blade draw-casting of the initial viscous LLC monomer gel; or roll-casting of the LLC mixture at elevated temperature. It is preferred that that coating be free of surface defects such as pinholes and scratches. In one embodiment, a commercial foam painting sponge or other such applicator may be used to apply the solution to the support. In another embodiment, the solution may be applied by roller casting. The amount of material on the support may be controlled by the number of applications and the concentration of the casting solution. If desired, more than one layer of solution may be applied to the support to form multiple layers of porous LLC polymer and thereby control the film thickness.

Some of the solution typically penetrates into the support, with the extent of penetration depending on the nature of the solution, the support, and the application process. The penetration of the solution into the support is believed to help attach the cross-linked LLC polymer film to the support. When the LLC phase is sensitive to the solvent content of the LLC mixture, the solvent content (e.g., water content) is controlled during processing to maintain the desired LLC phase. In one embodiment, the solvent content may be controlled by limiting evaporation of solvent from the film. Evaporation of the solvent may be controlled by sandwiching the LLC film and support between polymer sheets, processing the LLC film and support in an enclosure in which the atmosphere is controlled (e.g., the humidity level is controlled), and by other methods known to those skilled in the art. Enclosing the LLC film may also prevent other components from entering into LLC monomer film.

### Methods of the Invention

The invention includes a method of making modified porous LLC polymer membranes. In one embodiment, the invention includes a method for producing a surface modified porous LLC polymer membrane, the method comprising the step of depositing an inorganic material within the pores of the membrane using atomic layer deposition, wherein the inorganic material is attached to the interior pore surface of the membrane. Typically, the membrane is treated to remove water and/or other contaminants prior to the deposition step. Inorganic material may also be deposited on external surfaces of the membrane during the deposition process.

The invention also includes a method of using the modified membranes of the invention. In one embodiment, the invention includes a process of separating a component of a first fluid mixture, the process comprising the steps of bringing the first fluid mixture into contact with the inlet side of a separation membrane of the present invention; applying a pressure difference across said separation membrane; and withdrawing from the outlet side of the separation membrane a second fluid mixture wherein the proportion of the component is depleted, compared with the first fluid mixture. In this aspect of the invention, the “fluid” may be a liquid or a gas. Components that may be separated from a fluid mixture using the membranes of the invention include organic molecules, ions, gases, impurities and other contaminants.

The invention further includes a method of size-selective filtration of solutions using the membranes of the invention. One or more components such as nanometersize impurities, organic molecules, certain ions, and other contaminants may be removed from solution by selecting the pore diameter of the LLC membrane to be smaller than the molecular size of the component(s) of interest. In some of the methods of the invention, an inorganic material is deposited onto the pore surfaces inside the LLC polymer composition using atomic layer deposition (“ALD”; also known as ALE “atomic layer epitaxy”). ALD techniques permit the formation of inorganic deposits approximately equal to the molecular spacing of the inorganic material, typically up to about 0.01-0.4 nm of thickness per reaction cycle. In the ALD process, the inorganic deposit is formed in a series of two or more self-limited reactions, which in most instances can be repeated to sequentially form additional material until the inorganic deposit achieves a desired size or thickness (such as in the case of a film).

Every formulation or combination of components described or exemplified can be used to practice the invention, unless otherwise stated. Specific names of compounds are intended to be exemplary, as it is known that one of ordinary skill in the art can name the same compounds differently. When a compound is described herein such that a particular isomer or enantiomer of the compound is not specified, for example, in a formula or in a chemical name, that description is intended to include each isomers and enantiomer of the compound described individual or in any combination. Although the description herein contains many embodiments, these should not be construed as limiting the scope of the invention but as merely providing illustrations of some of the presently preferred embodiments of the invention.

All references throughout this application (for example, patent documents including issued or granted patents or equivalents; patent application publications; and non-patent literature documents or other source material) are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

Those skilled in the art will recognize, or be able to ascertain using no more than routine experimentation, numerous equivalents to the specific procedures, embodiments, claims, and examples described herein. Such equivalents were considered to be within the scope of this invention and covered by the claims appended hereto. For example, it should be understood, that modifications in reaction conditions, including but not limited to reaction times, reaction size/volume, and experimental reagents, such as solvents, catalysts, pressures, atmospheric conditions, e.g., nitrogen atmosphere, and reducing/oxidizing agents, with art-recognized alternatives and using no more than routine experimentation, are within the scope of the present application. In general the terms and phrases used herein have their art-recognized meaning, which can be found by reference to standard texts, journal references and contexts known to those skilled in the art. Any preceding definitions are provided to clarify their specific use in the context of the invention.

It is to be understood that wherever values and ranges are provided herein, all values and ranges encompassed by these values and ranges, are meant to be encompassed within the scope of the present invention. Moreover, all values that fall within these ranges, as well as the upper or lower limits of a range of values, are also contemplated by the present application.

The following examples further illustrate aspects of the present invention. However, they are in no way a limitation of the teachings or disclosure of the present invention as set forth herein.

### EXAMPLES

The invention is now described with reference to the following Examples. These Examples are provided for the purpose of illustration only, and the invention is not limited to these Examples, but rather encompasses all variations that are evident as a result of the teachings provided herein.

### Experimental

### Materials

Deionized water and TMA (97%, Sigma-Aldrich) were used as reactants.

### Alumina ALD on Supported Q_{I}-Phase LLC Polymer Membranes:

A flow-type reactor was used to deposit alumina on supported LLC polymer membranes by ALD. The system was operated at reduced pressures. A detailed description of the reactor system may be found elsewhere (H. Liang, L. F. Hakim, G. D. Zhan, J. A. McCormick, S. M. George, A. W. Weimer, J. A. Spencer, K. J. Buechler, J. Blackson, C. J. Wood, J. R. Dorgan, “Novel processing to produce polymer/ceramic nanocomposites by atomic layer deposition”, Journal of the American Ceramic Society 2007, 90(1):57-63).

In a typical run, two LLC polymer membranes were loaded into the reactor. Precursors were fed separately through the distributor of the reactor using the driving force of their vapor pressures. The reaction temperature was 65° C. Before the reaction, the membranes were degassed at 65° C. for ˜12 h. Each precursor was fed for enough time to make sure that all active sites were saturated. N₂ stream with a flow rate of 10 sccm was then fed as the purge gas to help remove unreacted precursor and any by-products formed during the reaction. The system was pumped down to 50 mtorr prior to the dose of the next precursor.

### Gas Permeation Tests:

Gas permeation studies were carried out using a time lag apparatus, in which a test membrane was clamped between two flanges, separating the feed and permeate reservoirs (i.e., two chambers), as described elsewhere (X. H. Liang, D. M. King, M, D. Groner, J. H. Blackson, J. D. Harris, S. M. George, A. W. Weimer, “Barrier properties of polymer/alumina nanocomposite membranes fabricated by atomic layer deposition”, Journal of Membrane Science 2008, 322(1):105-112). All membranes were degassed under vacuum overnight before testing at room temperature.

### Characterization:

The XRD spectra were obtained using an Inel CPS 120 diffraction system (CuKα radiation). The composition of deposited alumina was confirmed using a PHI 5600 X-ray photoelectron spectroscope (XPS) with a high energy resolution analyzer. The analysis was performed using an aluminum source, a pass energy of 187.85 eV, and an energy step of 0.4 eV. The cross-sectioned surface of polymer membrane was observed with a JEOL JSM-7401 F field emission scanning electron microscope (FESEM) equipped with an EDAXS detector unit for elemental analysis while imaging. Specimens were prepared by cutting the coated particles using a Super Gillette blue blade.

### Example 1

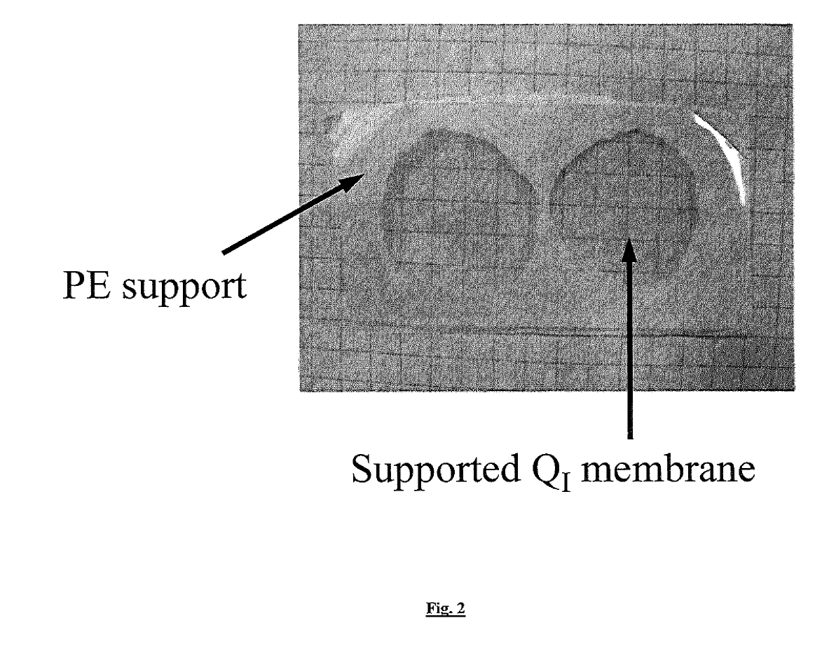

Supported Q_{I}-phase LLC polymer membranes were prepared as described in the literature (M. J. Zhou, P. R. Nemade, X. Y. Lu, X. H. Zeng, E. S. Hatakeyama, R. D. Noble, D. I. Gin, “New type of membrane material for water desalination based on a cross-linked bicontinuous cubic lyotropic liquid crystal assembly”, Journal of the American Chemical Society 2007, 129(31):9574-9575). The structure of these LLC polymer membranes was confirmed by powder X-ray diffraction (XRD) and chemical analysis, as described in the literature (M. J. Zhou, P. R. Nemade, X. Y. Lu, X. H. Zeng, E. S. Hatakeyama, R. D. Noble, D. L. Gin, “New type of membrane material for water desalination based on a cross-linked bicontinuous cubic lyotropic liquid crystal assembly”, Journal of the American Chemical Society 2007, 129(31):9574-9575). The resulting supported membranes were 30-35 μm thick, as observed by cross-sectional field emission scanning electron microscopy (FESEM), optically transparent, flexible and structurally stable under various test conditions, as illustrated in FIG. 2.

Alumina ALD was carried out by alternating reactions of trimethylaluminum (TMA) and water at 65° C. The LLC polymer membranes were coated with different numbers of ALD cycles from 1 to 20 cycles, and the coated samples were analyzed by XRD, X-ray photoelectron spectroscope (XPS), and energy dispersive spectroscopy (EDS) mapping to verify the structure of the Q_{I}-phase LLC polymer membranes and the deposition of alumina inside the porous structure.

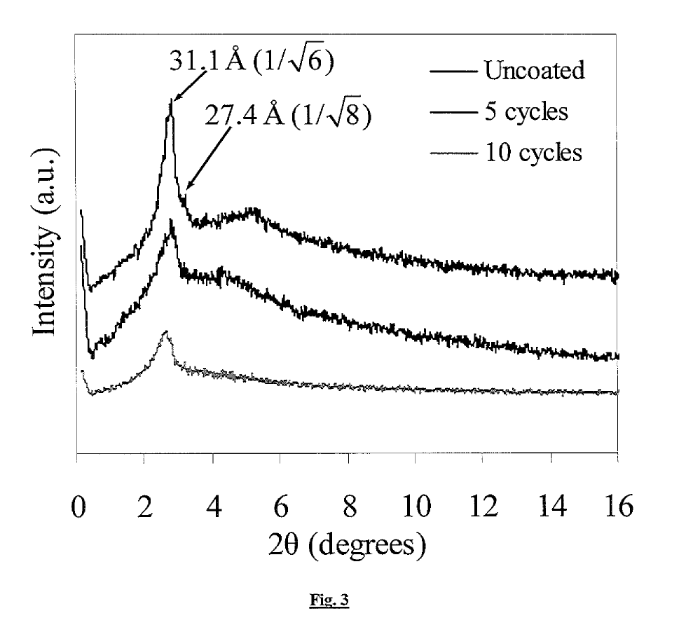

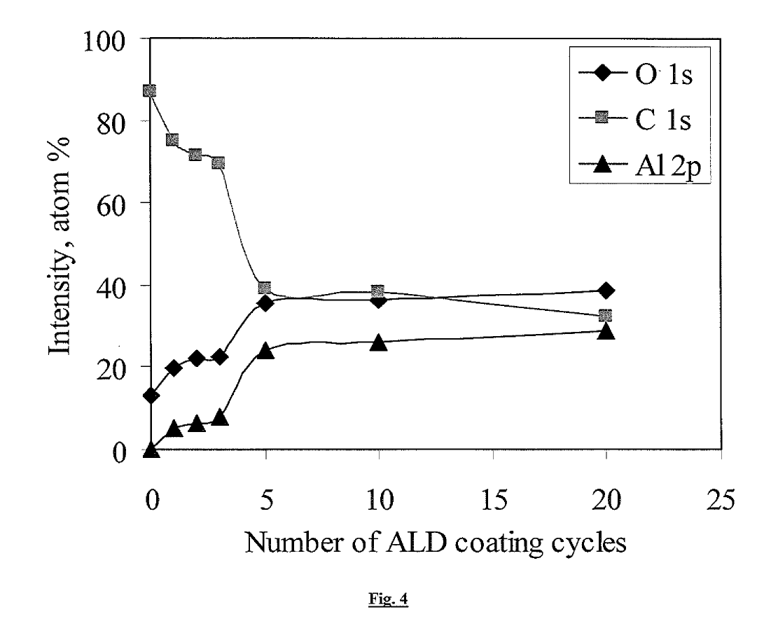

Powder XRD analysis of the alumina ALD-modified Q_{I}-phase LLC polymer membranes clearly showed two diffraction peaks that corresponded to a phase patterns, as illustrated in FIG. 3. Also, the d-spacing increased with more ALD coating cycles. The d-spacing of the first peak for 5 and 10 cycles of ALD coating was 31.2 and 32.9 Å, respectively. FIG. 4 illustrated the main element contents of the LLC polymer membranes after different alumina ALD coating cycles. XPS analysis indicated that alumina was deposited on the membranes during the 1^{st} ALD cycle. Alumina contents increased slowly from two to three cycles, and increased sharply from three to five cycles. The slower growth rate before three coating cycles indicated a short period of nucleation time was needed to initiate the alumina ALD on the LLC polymer membranes. Similar ALD nucleation phenomena have been observed for titania and alumina ALD on high density polyethylene (HDPE) particles without functional groups (X. H. Liang, D. M. King, P. Li, A. W. Weimer, “Low-temperature atomic layer-deposited TiO₂ films with low photoaetivity”, Journal of the American Ceramic Society 2009, 92(3):649-654; X. H. Liang, L. F. Hakim, G. D. Zhan, J. A. McCormick, S. M. George, A. W. Weimer, J. A. Spencer, K. J. Buechler, J. Blackson, C. J. Wood, J. R. Dorgan, “Novel processing to produce polymer/ceramic nanocomposites by atomic layer deposition”, Journal of the American Ceramic Society 2007, 90(1):57-63). The nucleation mechanism of alumina ALD on HOPE substrates using TMA and H₂O has been previously described in the literature (X. H. Liang, L. F. Hakim, G. D. Zhan, J. A. McCormick, S. M. George, A. W. Weimer, J. A. Spencer, K. J. Buechler, J. Blackson, C. J. Wood, J. R. Dorgan, “Novel processing to produce polymer/ceramic nanocomposites by atomic layer deposition”, Journal of the American Ceramic Society 2007, 90(1):57-63). The alumina ALD is conventionally thought to begin with native hydroxyl groups on the surface. The LLC polymer does not have hydroxyl groups, but the water in the nanopore network can react with TMA to initiate the alumina ALD in the 1^{st} coating cycle. After 5 coating cycles, the alumina content increased less sharply, which indicated that most of the Q_{I}-phase LLC nanopores were inaccessible to alumina precursors, especially for TMA. Therefore, alumina would mainly grow on the outside surface of the membrane, and less alumina signal would be detected by XPS with increasing ALD coating cycles, since the surface area of the porous material is mainly from the internal surface area of the nanopores and there was less surface area alumina ALD after five coating cycles. EDS mapping of the cross-sectioned samples verified that alumina was deposited in the interior of the membranes, and thus presumably inside the pores of the Q_{I}-phase LLC polymer membranes. The formed alumina was also distributed homogeneously on the cross-sectioned surface. Normally, during the nucleation period in ALD, alumina clusters are formed, instead of a continuous layer of alumina film; and the alumina ALD film growth rate is 0.1-0.4 nm after the nucleation period, depending on the reaction temperatures and substrate properties (Liang, 2007 and Liang 2008). In this case, the nanopores of the substrates are apparently inaccessible to alumina precursors after only five ALD coating cycles. Therefore, alumina deposition should be mainly in the form of alumina nanoparticles or clusters, as schematically illustrated in FIG. 1.

### Example 2

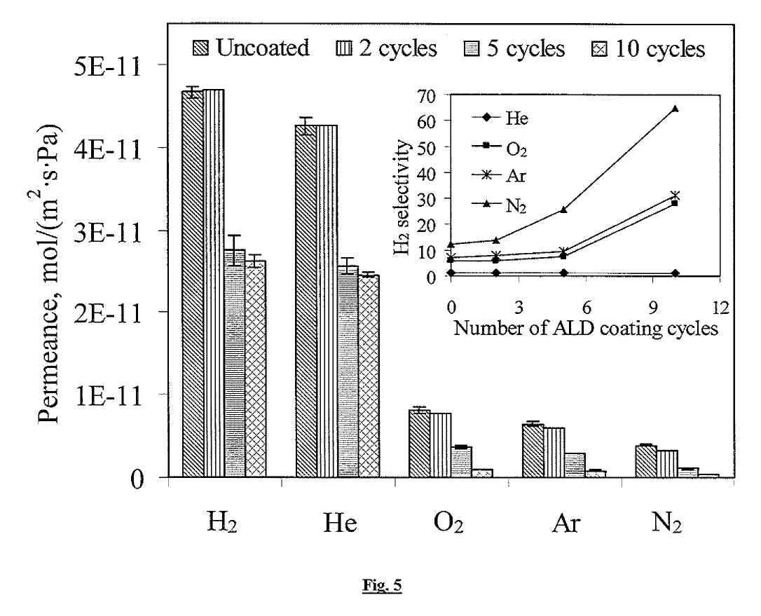

The potential of the resulting ALD-treated alumina-nanoparticle/Q_{I}-phase LLC composite membranes for light gas separations was subsequently evaluated. FIG. 5 illustrates the gas permeances and selectivities of the membranes after different numbers of ALD coating cycles. In general, gas permeances decreased with the increasing of ALD coating cycles, but the permeances of lighter gas, such as helium and hydrogen, were less affected by the ALD coating cycles with less than 10 coating cycles applied. The permselectivities (compared to hydrogen) of oxygen, argon and nitrogen increased with the increasing coating cycles. Especially for nitrogen, the perm selectivity increased from 12 to 65 with 10 cycles of alumina ALD coating. Further alumina ALD coatings may cover the pore entrance at the membrane surface and form one dense layer of film on the membrane surface, which would further reduce the gas permeance, even for helium and hydrogen.

Gas permeation studies for larger gas molecules, such as SF₆ (kinetic diameter=0.55 nm), indicated that the effective pore size of the ALD-modified Q_{I}-phase LLC polymer membranes was less than 0.55 nm after 10 cycles of alumina ALD coating. The permeance of the membrane for SF₆ decreased sharply with more ALD coating cycles, with no measured permeance after 10 cycles of alumina ALD coating.

These gas permeation studies show that alumina ALD can be used to effectively modify/reduce the effective pore size of nanoporous Q_{I}-phase LLC polymer membranes in a controllable fashion by only several ALD coating cycles (less than 10 cycles). In addition, water permeation studies with the pressure drop across the membrane of ˜50 psia indicated that the permeation of the LLC membrane with 1 cycle of alumina ALD was ˜10 times of that of the LLC membrane with 10 cycles of alumina ALD. The ability to modify or make nanopores in the ≦0.6 nm range in synthetic polymer membrane material is essentially unprecedented. These results are consistent with the requirement to form a defect-free, size- and shape-discrimination membrane for light gas separation, or even higher-resolution liquid water-based separations.

In summary, the use of alumina ALD to modify/reduce the effective pore size of nanoporous, supported Q_{I}-phase LLC polymer membranes was demonstrated. The resulting ALD-modified, cross-linked Q_{I}-phase LLC membranes showed promise as new nanoporous materials for light gas separations via molecular size discrimination, and should have similar application for even finer water purification applications. With 10 cycles of alumina ALD coating, the gas selectivity of H₂/N₂ was greatly increased from 12 to 65, while the gas permeance of H₂ only decreased −40%. The ALD approach described here is universal in nature, and may be applied to the modification of other nanoporous membranes for any sort of molecular-size-based porous separation of fluids (e.g., gas separation and water purification).

### REFERENCES

R. W. Baker, “Future directions of membrane gas separation technology”, Industrial & Engineering Chemistry Research 2002, 41(6):1393-1411
W. J. Koros, “Evolving beyond the thermal age of separation processes: Membranes can lead the way”, AIChE Journal 2004, 50(10):2326-2334
R. D. Noble, R. Agrawal, “Separations research needs for the 21^{st} century”, Industrial & Engineering Chemistry Research 2005, 44(9):2887-2892
J. G. Wijmans, R. W. Baker, “The solution-diffusion model-A review”, Journal of Membrane Science 1995, 107(1-2):1-21
D. L. Gin, J. E. Bara, R. D. Noble, B. J. Elliott, “Polymerized lyotropic liquid crystal assemblies for membrane applications”, Macromolecular Rapid Communications 2008, 29(5):367-389
B. D. Freeman, “Basis of permeability/selectivity tradeoff relations in polymeric gas separation membranes”, Macromolecules 1999, 32(2):375-380
S. S. Sablani, M. F. A. Goosen, R. AI-Belushi, M. Wilf, “Concentration polarization in ultrafiltration and reverse osmosis: a critical review”, Desalination 2001, 141(3):269-289
E. R. Nightingale, “Phenomenological theory of ion solution—effective radii of hydrogen ions”, Journal of Physical Chemistry 1959, 63(9):1381-1387
A. Bhattacharya, P. Ghosh, “Nanofiltration and reverse osmosis membranes: Theory and application in separation of electrolytes”, Reviews in Chemical Engineering 2004, 20(1-2):111-173
J. Caro, M. Noack, P. Kolsch, R. Schafer, “Zeolite membranes—state of their development and perspective”, Microporous and Mesoporous Materials 2000, 38(1):3-24 D. H. Kim, “Novel cation-selective mechanosensitive ion channel in the atrial cell-membrane”, Circulation Research 1993, 72(1):225-231
K. B. Jirage, J. C. Hulteen, C. R. Martin, “Nanotubule-based molecular-filtration membranes”, Science 1997, 278(5338):655-658
C. R, Martin, M. Nishizawa, K. Jirage, M. S. Kang, S. B. Lee, “Controlling ion transport selectivity in gold nanotubule membranes”, Advanced Materials 2001, 13(18):1351-1362
K. B. Jirage, C. R. Martin, “New developments in membrane-based separations”, Trends in Biotechnology 1999, 17(5):197-200
M. J. Zhou, T. J. Kidd, R. D. Noble, D. L. Gin, “Supported lyotropic liquid-crystal polymer membranes: Promising materials for molecular-size-selective aqueous nanofiltration”, Advanced Materials 2005, 17(15):1850-1853
M. J. Zhou, P. R. Nemade, X. Y. Lu, X. H. Zeng, E. S. Hatakeyama, R. D. Noble, D. L. Gin, “New type of membrane material for water desalination based on a cross-linked bicontinuous cubic lyotropic liquid crystal assembly”, Journal of the American Chemical Society 2007, 129(31):9574-9575
S. M. George, A. W. Ott, J. W, Klaus, “Surface chemistry for atomic layer growth”, Journal of Physical Chemistry 1996, 100(30:13121-13131
X. H. Liang, D. M. King, P. Li, A. W. Weimer, “Low-temperature atomic layer deposited TiO₂ films with low photoactivity”, Journal of the American Ceramic Society 2009, 92(3):649-654
X. H. Liang, L. F. Hakim, G. D. Zhan, J. A. McCormick, S. M. George, A. W.
Weimer, J. A. Spencer, K. J. Buechler, J. Blackson, C. J. Wood, J. R. Dorgan, “Novel processing to produce polymer/ceramic nanocomposites by atomic layer deposition”, Journal of the American Ceramic Society 2007, 90(1):57-63
X. H. Liang, G. D. Zhan, D. M. King, J. A. McCormick, J. Zhang, S. M, George, A. W. Weimer, “Alumina atomic layer deposition nanocoatings on primary diamond particles using a fluidized bed reactor”, Diamond and Related Materials 2008, 17(2):185-189
X. H. Liang, D. M, King, M, D. Groner, J. H. Blackson, J. D. Harris, S. M. George, A. W. Weimer, “Barrier properties of polymer/alumina nanocomposite membranes fabricated by atomic layer deposition”, Journal of Membrane Science 2008, 322(1):105-112
J. W. Klaus, A W. Ott, J. M. Johnson, S. M. George, “Atomic layer controlled growth of Si02 films using binary reaction sequence chemistry”, Applied Physics Letters 1997, 70(9):1092-1094
O. Shah, M. L. Wise, A. W. Ott, L, A Okada, S. M. George, “Atomic layer growth of Si02 on Si (100) and H2O using a binary reaction sequence”, Surface Science 1995, 334(1-3):135-152
J. D. Ferguson, A W, Weimer, and S. M. George, “Atomic layer deposition of Al₂O₃ films on polyethylene particles,” Chemistry of Materials 2004, 16(26):5602-5609
X. Auvray, T. Perche, C. Petipas, R. Anthore, M. J, Marti, I. Rico, A Lattes, “Influence of solvent headgroup interactions on the formation of lyotropic liquidcrystal phases of surfactants in water and nonaqueous protic and aprotic—solvents”, Langmuir 1992, 8(11):2671-2679
T. L. Greaves, C. J. Drummond, “Ionic liquids as amphiphile self-assembly media”, Chemical Society Reviews 2008, 37(8):1709-1726
B. A, Pindzola, J. Z. Jin, D. I. Gin, “Cross-linked normal hexagonal and bicontinuous cubic assemblies via polymerizable gemini amphiphiles”, Journal of the American Chemical Society 2003, 125(10):2940-2949

What is claimed is:

1. A composition comprising a nanoporous lyotropic liquid crystal (LLC) polymer membrane,
wherein the LLC polymer membrane comprises a LLC polymer comprising at least one pore,
wherein an inorganic material is attached to the interior surface of the at least one pore,
wherein the effective size of the at least one pore is less than 0.75 nm.

2. The composition of claim 1, wherein the inorganic material is deposited inside the at least one pore using atomic layer deposition.

3. The composition of claim 1, wherein the inorganic material comprises an oxide.

4. The composition of claim 3, wherein the oxide comprises at least one compound selected from the group consisting of alumina, titania, silica, zinc oxide, and a combination thereof.

5. The composition of claim 1, wherein the at least one pore has a structure selected from the group consisting of type I bicontinuous cubic (Q_{I}) LLC phase structure, and inverted hexagonal (H_{II}) LLC phase structure.

6. The composition of claim 1, wherein the LLC polymer is formed by polymerization of at least one polymerizable LLC monomer selected from the group consisting of monomer 1, monomer 1a, monomer 2, monomer 3, monomer 4, monomer 5, monomer 6, and a combination thereof.

7. The composition of claim 1, wherein the LLC polymer is embedded within a porous support membrane or deposited as a layer on the surface of a porous support membrane.

8. A method of preparing a nanoporous lyotropic liquid crystal (LLC) polymer membrane, wherein the method comprises the steps of:
providing a LLC polymer membrane,
wherein the LLC polymer membrane comprises a LLC polymer comprising at least one pore; and,
depositing an inorganic material within the at least one pore,
wherein the inorganic material is attached to the interior surface of the at least one pore, and,
wherein upon depositing of the inorganic material the effective size of the at least one pore is less than 0.75 nm;
thereby forming the nanoporous LLC polymer membrane.

9. The method of claim 8, wherein the depositing is performed using atomic layer deposition.

10. The method of claim 8, wherein the inorganic material comprises at least one oxide selected from the group consisting of alumina, titania, silica, zinc oxide, and a combination thereof.

11. The method of claim 8, wherein the at least one pore has a structure selected from the group consisting of type I bicontinuous cubic (Q_{I}) LLC phase structure, and inverted hexagonal (H_{II}) LLC phase structure.

12. The method of claim 8, wherein the LLC polymer is formed by polymerization of at least one polymerizable LLC monomer selected from the group consisting of monomer 1, monomer 1a, monomer 2, monomer 3, monomer 4, monomer 5, monomer 6, and a combination thereof.

13. The method of claim 8, wherein the LLC polymer is embedded within a porous support membrane or deposited as a layer on the surface of a porous support membrane.

14. A method of performing size-selective separation of a given component in a fluid mixture, wherein the method comprises the steps of:
providing the fluid mixture comprising the given component;
contacting the fluid mixture with one surface of a nanoporous lyotropic liquid crystal (LLC) polymer membrane,
wherein the LLC polymer membrane comprises a LLC polymer comprising at least one pore,
wherein an inorganic material is attached to the interior surface of the at least one pore, and,
wherein the effective size of the at least one pore is less than 0.75 nm;
applying a pressure difference across the nanoporous LLC polymer membrane; and,
isolating a filtered composition from the opposite surface of the LLC polymer membrane,
wherein the ratio of the given component in the filtered composition is distinct from the ratio of the given component in the fluid mixture, thereby performing the separation of the given component.

15. The method of claim 14, wherein the effective diameter of the at least one pore is lower than the kinetic diameter of the given component.

16. The method of claim 14, wherein the inorganic material comprises at least one oxide selected from the group consisting of alumina, titania, silica, zinc oxide, and a combination thereof.

17. The method of claim 14, wherein the at least one pore has a structure selected from the group consisting of type I bicontinuous cubic (Q_{I}) LLC phase structure, and inverted hexagonal (H_{II}) LLC phase structure.

18. The method of claim 14, wherein the LLC polymer is formed by polymerization of at least one polymerizable LLC monomer selected from the group consisting of monomer 1, monomer 1a, monomer 2, monomer 3, monomer 4, monomer 5, monomer 6, and a combination thereof.

19. The method of claim 14, wherein the LLC polymer is embedded within a porous support membrane or deposited as a layer on the surface of a porous support membrane.

20. The method of claim 14, wherein the fluid mixture is a gas or a liquid.
